(19) United States
(12) Patent Application Publication
(10) Pub. No.: US 2024/0418764 A1
(43) Pub. Date: Dec. 19, 2024

(54) FAULT POINT LOCATER, FAULT POINT LOCATING SYSTEM, AND FAULT POINT LOCATING METHOD FOR POWER SYSTEM

(71) Applicant: Mitsubishi Electric Corporation, Tokyo (JP)

(72) Inventors: Yusuke MORITA, Tokyo (JP); Kazuhiro YASUNAMI, Tokyo (JP)

(73) Assignee: Mitsubishi Electric Corporation, Tokyo (JP)

(21) Appl. No.: 18/734,789

(22) Filed: Jun. 5, 2024

(30) Foreign Application Priority Data
Jun. 19, 2023 (JP) 2023-099908

(51) Int. Cl. G01R 31/08; G06N 3/096

(52) U.S. Cl. CPC G01R 31/088; G01R 31/086; G06N 3/096

(57) ABSTRACT

A data acquisition unit acquires current information and voltage information at a predetermined spot at a time of fault occurrence. A location result inferring unit receives input of the current information and voltage information obtained by the data acquisition unit and an estimated fault cause based on the current information and the voltage information and outputs a location result that quantifies a probability of existence of fault point on a power system.

### CROSS REFERENCE TO RELATED APPLICATIONS

This nonprovisional application is based on Japanese Patent Application No. 2023-099908 filed on Jun. 19, 2023 with the Japan Patent Office, the entire contents of which are hereby incorporated by reference.

### BACKGROUND OF THE INVENTION

### Field of the Invention

The present disclosure relates to a fault point locater, a fault point locating system, and a fault point locating method.

### Description of the Background Art

In the event of a fault in a power transmission line of a power system, early discovery of the spot where the fault occurs (hereinafter referred to as “fault point”) is important for early recovery from the fault. As a fault point locater for this, Japanese Patent Laying-Open No. 2003-114249 (hereinafter referred to as PTL 1) discloses a technique for locating a fault section by a neural network approach based on the detected current information in a power transmission line fault by a sensor attached to an overhead ground wire of an overhead power line.

As an example of locating a power transmission line fault in a power system, “Survey Results of Fault Location in Power Systems” Shoichi Urano, IEEJ Transactions of Power and Energy Vol. 137 No. 4 pp. 261-264 (hereinafter referred to as NPL 1) discloses an impedance approach which locates a fault point by determining an impedance from measurement values of current and voltage at the time of a fault. In particular, as an example of the impedance approach, NPL 1 describes a digital impedance approach that can be incorporated in a digital relay for power transmission line protection. In the digital impedance approach, when a measurement value only of one terminal is used, a fault point is located under a condition that voltage and current at the fault point are of the same phase, assuming that the resistance at the fault point is pure resistance. The fault point can be located using the impedance calculated under the above assumption as well as system information including topology and impedance of the power system (power transmission system and power distribution system).

### SUMMARY OF THE INVENTION

Unfortunately, the fault point locater in PTL 1 requires installation of a sensor on an overhead ground wire and a configuration for transmitting measurement information by the sensor, increasing costs including system construction costs (initial cost) and operating costs (running cost). Moreover, PTL 1 fails to locate a fault point in a case such as a short-circuit fault where faulty current does not flow through the overhead ground wire, and is unable to be applied to an underground cable or power distribution line with no overhead ground wire.

On the other hand, the impedance approach in NPL 1 can acquire measurement information for locating a fault point using an existing instrument installed at an electric power station such as a power plant or a substation. However, there may be a plurality of estimated fault points where the electrical distance from the electric power station matches the calculated impedance, and in such a case, the fault point cannot be identified early.

The present disclosure is made to solve such a problem, and an object of the present disclosure is to locate a fault point inexpensively and accurately in the event of a fault and promote efficient maintenance and conservation of a power system.

An aspect of the present disclosure provides a fault point locater for a power system. The fault point locater includes a data acquisition unit and an inference unit. The data acquisition unit acquires current information and voltage information at a predetermined spot at a time of fault occurrence. The inference unit receives input of the current information and voltage information obtained by the data acquisition unit and an estimated fault cause based on the current information and voltage information at a time of fault occurrence and outputs a location result that quantifies a probability of existence of fault point on the power system.

Another aspect of the present disclosure provides a fault point locating method for a power system. The fault point locating method involves acquiring current information and voltage information at a predetermined spot at a time of fault occurrence; and receiving input of the acquired current information and voltage information and an estimated fault cause based on the current information and voltage information and outputting a location result that quantifies a probability of existence of fault point on the power system.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic diagram illustrating a fault point locater according to a comparative example.

FIG. 2 is a schematic diagram illustrating a configuration of a fault point locating system including a fault point locater according to a first embodiment.

FIG. 3 is a block diagram illustrating a functional configuration example of the fault point locater shown in FIG. 2.

FIG. 4 is a block diagram illustrating a functional configuration example of the fault point locating server shown in FIG. 2.

FIG. 5 is a block diagram illustrating a configuration example of a computer system for implementing the functions of the fault point locater and the fault point locating server.

FIG. 6 is a block diagram illustrating input/output in a learning phase of a fault point inference model in the first embodiment.

FIG. 7 is a block diagram illustrating input/output of a statistical model.

FIG. 8 is a conceptual diagram illustrating an output example of the statistical model.

FIG. 9 is a flowchart illustrating the process of inputting and storing system information shown in FIG. 3 and FIG. 4.

FIG. 10 is a flowchart illustrating the process of generating and storing training data and a trained model for the fault point inference model shown in FIG. 6 and the trained model.

FIG. 11 is a flowchart illustrating the process of generating and storing the statistical model shown in FIG. 6.

FIG. 12 is a flowchart illustrating the process for fault point location at the time of system fault occurrence in the fault point locating system according to the first embodiment.

FIG. 13 is a block diagram illustrating fault point location according to the first embodiment.

FIG. 14 is a conceptual diagram illustrating an output example of a fault point location result.

FIG. 15 is a block diagram illustrating a configuration example of a fault point locater according to a modification of the first embodiment.

FIG. 16 is a block diagram illustrating input/output in a learning phase of a fault point inference model in a second embodiment.

FIG. 17 is a block diagram illustrating fault point location according to the second embodiment.

FIG. 18 is a flowchart illustrating the process for fault point location at the time of system fault occurrence in the fault point locating system according to the second embodiment.

### DESCRIPTION OF THE PREFERRED EMBODIMENTS

Embodiments of the present disclosure will be described in detail below with reference to the drawings. In the following, like or corresponding parts in the drawings are denoted by like reference signs and a description thereof will basically not be repeated.

### First Embodiment

### (Description of Comparative Example)

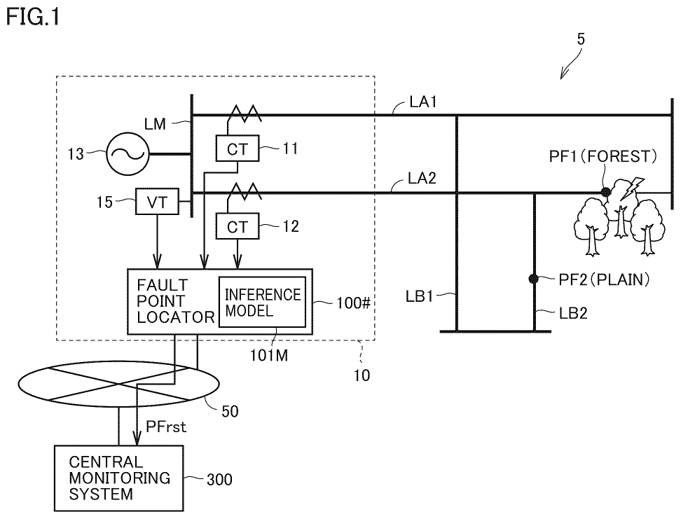

FIG. 1 is a schematic diagram illustrating a fault point locater according to a comparative example.

Referring to FIG. 1, a fault point locater 100 #according to a comparative example locates a fault point at the time of fault occurrence in a power system 5. In the simplified example in FIG. 1, power system 5 includes an electric power station 10 including a bus LM and an AC power source 13, power transmission lines LA1, LA2 connected to bus LM supplied with electric power from AC power source 13, a power transmission line LB1 branching from power transmission line LA1, and a power transmission line LB2 branching from power transmission line LA2. Electric power station 10 encompasses a power plant and a substation or the like.

In electric power station 10, bus LM is provided with a voltage transformer (VT) 15 for measuring voltage, and power transmission lines LA1 and LA2 are provided with current transformers (CT) 11 and 12, respectively, for measuring current. Measurement values of voltage transformer 15 and current transformers 11, 12 are transmitted to fault point locater 100#.

Fault point locater 100# is disposed, for example, at electric power station 10 and communicatively connected to a central monitoring system 300 through a communication network 50. Electric power station 10 may be under unmanned operation. A fault point location result PFrst calculated by fault point locater 100# using current information and voltage information at the time of fault occurrence is transmitted to central monitoring system 300 through communication network 50. The voltage information includes at least one of phase voltages of A phase, B phase, and C phase, zero-phase voltage, and line-to-line voltages of AB phase, BC phase, and CA phase. The current information includes at least one of phase currents of A phase, B phase, and C phase, zero-phase current, and line-to-line currents of AB phase, BC phase, and CA phase. These current information and voltage information can be measured by CT and VT in electric power station 10 and stored, and then transmitted from CT and VT.

Central monitoring system 300 corresponds to a manned control center. Fault point information indicated by fault point location result PFrst can be provided to maintenance workers from an operator of the control center or automatically from central monitoring system 300 or a system associated with central monitoring system 300. The maintenance workers are dispatched for identification of the actual fault point and finding of the cause to ensure recovery work.

Fault point locater 100# in the comparative example is configured to store an inference model 101M based on the digital impedance approach described in NPL 1. Thus, inference model 101M receives input of current information and voltage information at the time of a fault measured by current transformers (CT) 11, 12 and voltage transformer (VT) 15 and outputs the location result of the fault point located based on an impedance calculated value from electric power station 10 to the fault point.

Specifically, the fault point can be located by indicating the electrical distance on the power transmission path from electric power station 10, using the impedance calculated value and system information including the topology and impedance of the power system. Inference model 101M can be constructed, for example, using a machine-trained neural network model in the same manner as in PTL 1.

However, a spot with an equal impedance from electric power station 10 exists for each power transmission path. For example, in the example in FIG. 1, when a fault occurrence in the system of power transmission line LA2 is detected from current information and voltage information measured by current transformers (CT) 11, 12 and voltage transformer (VT) 15 in electric power station 10, PF1 on power transmission line LA2 and PF2 on a path of a power transmission line LA2-LB2 exist as points having an electrical distance corresponding to the impedance calculated value from current information and voltage information. However, with inference model 101M based on the impedance approach, it is difficult to identify which of PF1 and PF2 is the fault point.

Another cause of decreasing the accuracy in fault point location is that arc resistance at a fault point varies with the fault cause. Arc resistance typically exhibits a value that varies with the fault cause. For example, the arc resistance value is relatively high in a fault caused by contact with trees, and the arc resistance value is relatively low in a fault caused by contact with metals.

Since the impedance value calculated from current information and voltage information includes an arc resistance value, the existence of the arc resistance value itself may cause an error between the fault point located based on the impedance value and the actual fault point. Furthermore, when absorption of an error of the arc resistance value by a learning model is contemplated, variations in arc resistance value depending on the fault cause as described above may cause a learning error, which decreases the accuracy in fault point location result.

In this way, it is understood that fault point locater 100# according to the comparative example can construct a learning model without requiring new sensor arrangement as in PTL 1 while it has room for improvement in accuracy in fault point location.

### (Description of First Embodiment)

A fault point locater according to a first embodiment is configured as described below for improving accuracy in fault point location, compared to the comparative example.

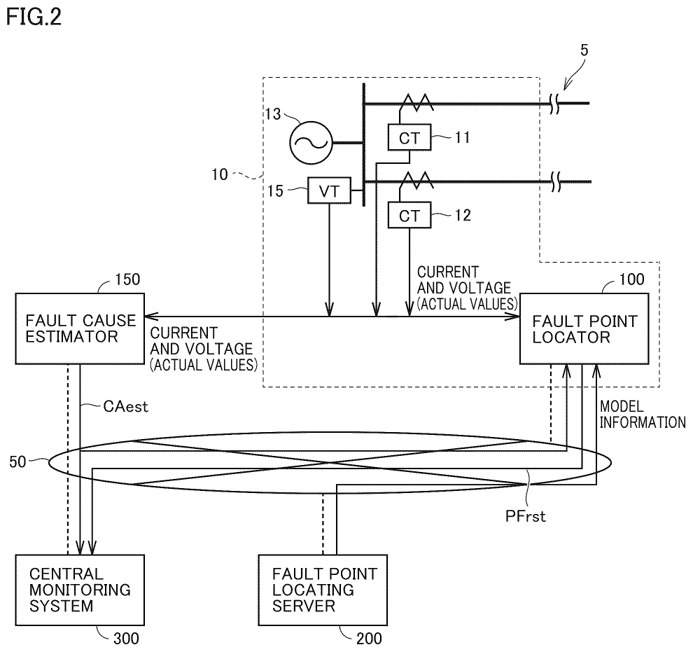

FIG. 2 is a schematic diagram illustrating a configuration of a fault point locating system including a fault point locater 100 according to the first embodiment.

Referring to FIG. 2, the fault point locating system includes fault point locater 100 and a fault point locating server 200 communicatively connected to each other through a communication network 50. A central monitoring system 300 similar to that in FIG. 1 is also connected to communication network 50. Further, a fault cause estimator 150 is disposed as an external device of the fault point locating system.

Current information and voltage information measured by current transformers (CT) 11, 12 and voltage transformer (VT) 15 are transmitted to fault point locater 100 and fault cause estimator 150 in the same manner as in FIG. 1. For example, current transformers (CT) 11, 12 and voltage transformer (VT) 15 are cable-connected to each of fault point locater 100 and fault cause estimator 150 to transmit current information and voltage information. Hereinafter, current information and voltage information transmitted from current transformers (CT) 11, 12 and voltage transformer (VT) 15 may be denoted as current and voltage (actual values). In this way, it should be noted that the application of the present embodiment does not require arrangement of a special detector (sensor). Unlike PTL 1, this configuration enables fault point location without involving cost increase.

At the time of fault occurrence, fault cause estimator 150 outputs estimated fault cause CAest, based on current and voltage (actual values). Fault cause estimator 150 can be implemented by any known technique, for example, may be configured with the information processing apparatus described in Japanese Patent Laying-Open No. 2021-19480. In the present disclosure, estimated fault cause CAest may be generated by fault cause estimator 150 by any method, and fault cause estimator 150 may be acquired additionally using information other than current and voltage (actual values) input to fault point locater 100. Fault cause estimator 150 is input to fault point locater 100 through communication network 50 using the Internet protocol (IP).

Fault point locater 100 and fault cause estimator 150 according to the first embodiment can basically be disposed in electric power station 10, in the same manner as in fault point locater 100# in FIG. 1. Thus, as shown in FIG. 2, current and voltage (actual values) can be input to fault point locater 100 and fault cause estimator 150 without passing through communication network 50 using the Internet protocol (IP).

Alternatively, current and voltage (actual values) may be input to fault point locater 100 or fault cause estimator 150 through communication network 50 using the Internet protocol (IP). This configuration increases the degree of freedom in arrangement of fault point locater 100 and fault cause estimator 150.

In the fault point locating system shown in FIG. 2, fault point locater 100 receives a model created by fault point locating server 200 through communication network 50 and outputs fault point location result PFrst obtained by inferring a fault point, using the model, the current and voltage (actual values) at the time of fault occurrence, and estimated fault cause CAest from fault cause estimator 150. In the present embodiment, fault point location result PFrst quantifies the probability of existence of fault point on power system 5.

Fault point location result PFrst from fault point locater 100 is transmitted to central monitoring system 300 through communication network 50 in the same manner as in FIG. 1. Specifically, fault point location result PFrst is provided to a maintenance worker from an operator of a control center having central monitoring system 300 or automatically from central monitoring system 300 or a system associated with central monitoring system 300. Improving the accuracy of fault point information based on fault point location result PFrst enables identification of a fault point and finding of the cause as well as shorter recovery time (for example, from a blackout). As a result, efficient maintenance and conservation of power system 5 can be achieved.

Central monitoring system 300 corresponds to, for example, a system such as energy management system (EMS) or supervisory control and data acquisition (SCADA) installed at a central load dispatching center, a trunk power system load dispatching center, or a local load dispatching center, or a power distribution automation system.

In this way, in the present embodiment, fault point locater 100 and fault point locating server 200 that constitute the fault point locating system are connected through the above communication network 50, so that information can be transmitted and received between fault point locater 100 and fault point locating server 200. Fault point locater 100 and fault point locating server 200 that constitute the fault point locating system are also connected to fault cause estimator 150, central monitoring system 300, and the like through communication network 50 so that fault point locater 100, fault cause estimator 150, fault point locating server 200, and central monitoring system 300 can transmit and receive data and information with each other through communication network 50.

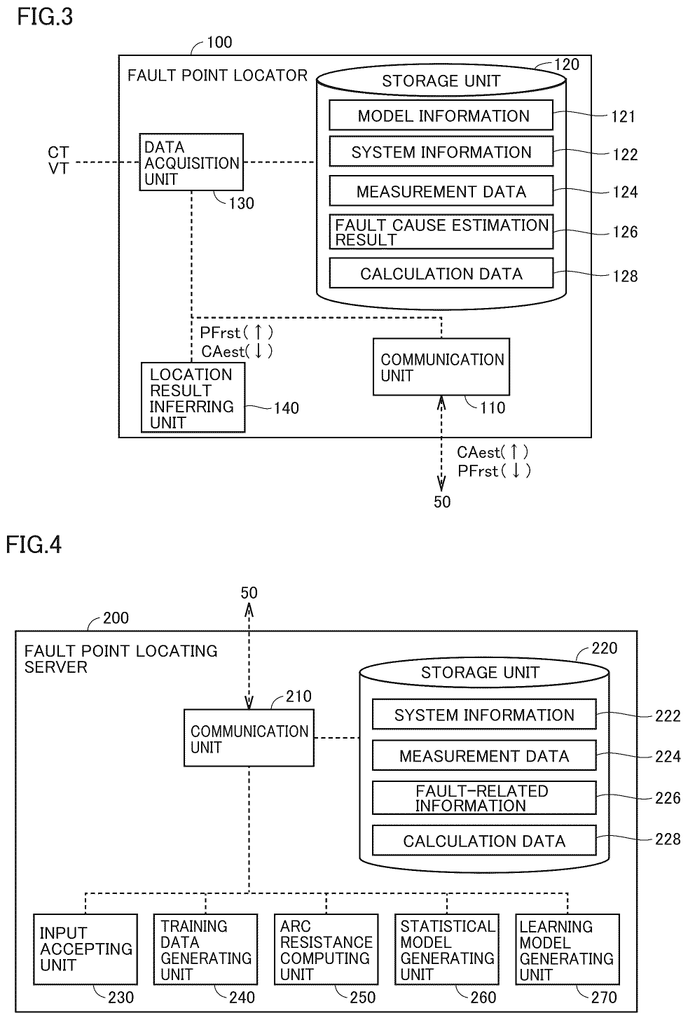

FIG. 3 is a block diagram illustrating a functional configuration example of the fault point locater shown in FIG. 2.

As shown in FIG. 3, fault point locater 100 includes a communication unit 110, a storage unit 120, a data acquisition unit 130, and a location result inferring unit 140.

Communication unit 110 has a function for communicating with an external device through communication network 50.

Data acquisition unit 130 acquires current and voltage (actual values) from current transformers (CT) 11, 12 and voltage transformer (VT) 15 that are received by communication unit 110. Thus, current information and voltage information at current transformers (CT) 11, 12 and voltage transformer (VT) 15 in electric power station 10, which are an example of “predetermined spot”, are acquired.

Storage unit 120 can read and write data between communication unit 110, data acquisition unit 130, and location result inferring unit 140. Storage unit 120 can also transmit and receive data with an external device connected to communication network 50, such as fault point locating server 200, via communication unit 110.

Storage unit 120 has a storage area for each of model information 121, system information 122, measurement data 124, fault cause estimation result 126, and calculation data 128.

Model information 121 includes information for constructing a trained model and a statistical model described later. System information 122 includes information on the topology and impedance of power system 5. Model information 121 and system information 122 are sent from fault point locating server 200 via communication network 50, received by communication unit 110, and then stored into storage unit 120.

Measurement data 124 includes current and voltage (actual values) acquired by data acquisition unit 130. The current and voltage (actual values) are sent by communication unit 110 to fault point locating server 200 through communication network 50 and stored on the fault point locating server 200 side.

Fault cause estimation result 126 includes estimated fault cause CAest output from fault cause estimator 150 at the time of fault occurrence. Calculation data 128 includes fault point location result PFrst obtained by location result inferring unit 140.

At the time of fault occurrence in power system 5, location result inferring unit 140 acquires, from storage unit 120, current and voltage (actual values) (measurement data 124) which are current information and voltage information at the time of fault occurrence, estimated fault cause CAest (fault cause estimation result 126), and a trained model and an arc resistance value statistical model (model information 121), as well as topology and impedance information of power system 5 (system information 122).

As will be explained in detail later, location result inferring unit 140 inputs current and voltage (actual values) at the time of fault occurrence and estimated fault cause CAest from fault cause estimator 150 to the trained model and calculates a fault point location result. Location result inferring unit 140 corresponds to an example of “inference unit”.

Furthermore, as will be explained in detail later, location result inferring unit 140 inputs estimated fault cause CAest from fault cause estimator 150 to the arc resistance value statistical model, acquires the probabilistic distribution of arc resistance value, and then outputs fault point location result PFrst by integrating the calculation result by the trained model and the probabilistic distribution. Fault point location result PFrst output from location result inferring unit 140 is stored as calculation data 128 into storage unit 120 and sent by communication unit 110 to fault point locating server 200 and central monitoring system 300 through communication network 50.

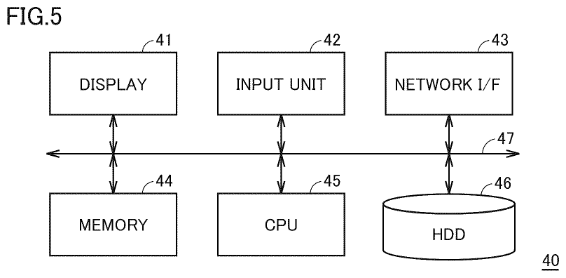

Therefore, fault point locater 100 is typically installed in electric power station 10 (power plant or substation) and has the following functions.
(1) Perform a process of receiving the trained model and the arc resistance value statistical model from fault point locating server 200 and storing them as model information 121.
(2) At the time of fault occurrence in power system 5, perform a process of acquiring and storing current information and voltage information (current and voltage (actual values)) at the time of a fault from voltage transformer (VT) and current transformer (CT) in electric power station 10, and sending them to fault point locating server 200.
(3) At the time of fault occurrence in power system 5, perform a process of receiving (acquiring) and storing the fault cause estimation result (estimated fault cause CAest) from fault cause estimator 150 separately installed.
(4) At the time of fault occurrence in power system 5, perform a process of locating the fault point, using the current information and voltage information (current and voltage (actual values)) and the fault cause estimation result (estimated fault cause CAest) as input data to the trained model and the arc resistance value statistical model, and outputting and storing the result (fault point location result PFrst).
(5) Perform a process of sending the location result of the fault point (fault point location result PFrst) to central monitoring system 300 with the presence of operators. FIG. 4 is a block diagram illustrating a functional configuration example of the fault point locating server shown in FIG. 2.

As shown in FIG. 4, fault point locating server 200 includes a communication unit 210, a storage unit 220, an input accepting unit 230, a training data generating unit 240, an arc resistance computing unit 250, a statistical model generating unit 260, and a learning model generating unit 270.

Communication unit 210 has a function for communicating with an external device through communication network 50. Upon occurrence of a fault, communication unit 210 receives current and voltage (actual values) from fault point locater 100 through communication network 50 at a given timing and receives estimated fault cause CAest output at the time of fault occurrence from fault cause estimator 150. Fault point locating server 200 thus can acquire current and voltage (actual values) and estimated fault cause CAest when a system fault occurs.

Storage unit 220 can write and read data between communication unit 210, input accepting unit 230, training data generating unit 240, arc resistance computing unit 250, statistical model generating unit 260, and learning model generating unit 270. Storage unit 220 can also send and receive data with an external device connected to communication network 50, such as fault point locater 100, via communication unit 210.

Storage unit 220 has a storage area for each of system information 222, measurement data 224, fault-related information 226, and calculation data 228.

System information 222 includes information on the topology and impedance of power system 5 and information indicating the surrounding situation of each of a plurality of points of power system 5.

Measurement data 224 includes information on various currents and voltages. The current and voltage (actual values) received by communication unit 210 in response to fault occurrence can be stored as measurement data 224 in storage unit 220.

Fault-related information 226 includes a fault point and a fault cause (actual) which are actual values at the time of fault occurrence and an arc resistance value (calculated value) calculated by arc resistance computing unit 250. Further, estimated fault cause CAest output at the time of fault occurrence from fault cause estimator 150, which is received by communication unit 210, can also be stored as fault-related information 226 in storage unit 220.

Calculation data 228 includes training data (teacher data) for use in machine learning of a model, and data indicating a trained model and a statistical model.

Input accepting unit 230 receives input of information on the system topology and impedance or information on the surrounding situation for power system 5 and stores the received information as system information 222 into storage unit 220. Similarly, at the time of system fault occurrence (more precisely, after fault inspection carried out after the system fault), input accepting unit 230 receives input of actual values of the fault point and the fault cause and stores the received actual values as fault-related information 226 into storage unit 220.

Training data generating unit 240 can acquire information on the topology and impedance of power system 5 from system information 222 stored in storage unit 220 and construct an instantaneous value analysis model of power system 5. The instantaneous value analysis model can be constructed, for example, but not limited to, by known simulation tools such as Electro-Magnetic Transient Program (EMTP), PSCAD (registered trademark), and XTAP (registered trademark).

On the instantaneous value analysis model, currents and voltages at installation points of VT(15) and CT(11, 12) (electric power station 10 such as power plant or substation) at the time of fault occurrence at various spots (fault points) are calculated by simulation to generate the calculated values of current data and voltage data (hereinafter also referred to as current and voltage (calculated values). Training data generating unit 240 thus can acquire, as training data for use in machine learning, a set of the fault point and the corresponding current data and voltage data (calculated value) for each assumed fault condition. The calculated training data can be stored as calculation data 228 in storage unit 220.

Arc resistance computing unit 250 acquires the fault point and fault cause (actual) and the current and voltage (actual values) at the time of a fault from fault-related information 226 stored in storage unit 220 and further acquires information on the topology and impedance of power system 5 from system information 222 stored in storage unit 220 to calculate the arc resistance value (calculated value) in each fault. The calculated arc resistance value (calculated value) is stored as fault-related information 226 in storage unit 220.

Statistical model generating unit 260 acquires fault causes (actual) (or fault cause (estimate)) and arc resistance values (calculated values) in a plurality of fault cases in the past from fault-related information 226 in storage unit 220. Further, an arc resistance statistical model is generated using the acquired data. Data for representing the generated statistical model is stored as calculation data 228 in storage unit 220.

Learning model generating unit 270 acquires information indicating the topology and information on the impedance of power system 5, and the surrounding situation on each spot in power system 5, from system information 222 stored in storage unit 220. Learning model generating unit 270 further acquires a set of current and voltage (calculated values) obtained by simulation calculation, which is training data, from calculation data 228 stored in storage unit 220 and the corresponding fault point and fault cause (actual or estimate) from fault-related information 226 stored in storage unit 220, and performs machine learning for generating a fault point inference model. The fault point inference model will be described in detail later. Information for indicating the fault point inference model obtained as a trained model as a result of machine learning is stored as calculation data 228 in storage unit 220.

Fault point locating server 200 may be disposed at any place such as a server site or a business place as long as it can communicate with fault point locater 100 through communication network 50, and may be constructed with a cloud system. According to the configuration in FIG. 4, fault point locating server 200 has the following functions.
(6) Accept and acquire input of information such as the topology and impedance of power system 5 and the surrounding situation of each spot (or refer to a database residing externally to the fault point locating system through communication network 50) and store the acquired information.
(7) At the time of system fault occurrence, receive (acquire) current information and voltage information (current and voltage (actual values)) measured by CT(current transformer) or VT(voltage transformer) in electric power station 10, as current and voltage (actual values) at the time of a fault, from fault point locater 100, and store the received information.
(8) Accept and acquire input of the fault point (actual) and the fault cause (actual) that are determined in inspection after a system fault (or refer to a system fault-related database residing externally to the fault point locating system through communication network 50) and store the acquired information.
(9) Acquire and store calculated values of current and voltage by CT and VT in electric power station 10 under each fault condition obtained by generating the instantaneous value analysis model described above for the target power system 5 using the system information (topology, impedance) and performing instantaneous value analysis that simulates various fault conditions (various fault points and fault phases). The stored calculated values of current and voltage serve as training data for use in machine learning described later.
(10) Calculate an arc resistance value by performing electrical calculation from the current and voltage (actual values) measured at the time of a system fault, fault point (actual), system information (topology, impedance), and the like, and store the result of calculation. The arc resistance value can be calculated using any calculation method, but using a simulation tool for instantaneous value analysis described above is presumably most efficient.
(11) Generate a statistical model from the fault cause (basically the actual one is used but the estimation result may be used) and the arc resistance value (calculated value), and store the generated statistical model. As the statistical model, for example, a histogram, or a probability density function, a probability distribution function, or a cumulative distribution function obtained from the histogram using a parametric approach or a non-parametric approach can be generated and stored. The least square method may be used as the parametric approach but any method may be used. Similarly, the kernel density estimation method may be used as the non-parametric approach but any method may be used.
(12) Generate a machine learning model (trained model) by machine learning using the training data generated in (9) above and store the generated machine learning model. Specifically, machine learning is performed using the current and voltage (calculated values) and the fault cause presumable (possible) from the surrounding situation at each spot in power system 5 as “features (input data to the machine learning model at the time of inference)” and using the fault point (a fault point or a section including a fault point set (simulated) as a fault condition at the time of instantaneous value analysis) as “answer (that is, the output data from the machine learning model), whereby a fault point inference model which is a trained model is generated and stored. Non-limiting examples of the method of machine learning that can be used include decision tree, random forest, ANN (neural network), and support vector machine (SVM). Machine learning can basically be used as “regression approach”. In this case, the fault point can be represented by a combination of the power transmission path and the distance from electric power station 10 on power system 5. Machine learning may be used as “classification approach”. In this case, the power transmission line and the power distribution line in power system 5 are divided into a plurality of sections, and to which of the sections the fault point belongs is acquired by the learning model. For example, the probability of existence of fault point in each section can be determined from the learning model.
(13) Perform a process of sending “trained model”, “statistical model”, “system topology”, and “impedance” to the fault point locater 100. FIG. 5 is a diagram illustrating a configuration example of a computer system for implementing the functions of fault point locater 100 and fault point locating server 200.

As shown in FIG. 5, a computer system 40 can be a common configuration including a display 41, an input unit 42, a network interface (I/F) 43, a memory 44, a central processing unit (CPU) 45, a hard disk drive (HDD) 46, and a bus 47.

Fault point locater 100 shown in FIG. 3 can be implemented as follows using computer system 40.

Specifically, the functions of data acquisition unit 130 in FIG. 3 are implemented by a not-shown analog-to-digital converter (A/D converter) in input unit 42 in FIG. 5. The functions of communication unit 110 in FIG. 3 can be implemented by CPU 45 and network I/F 43 in FIG. 5. The functions of storage unit 120 in FIG. 3 can be implemented using a partial area of HDD 46 in FIG. 5. The functions of location result inferring unit 140 in FIG. 3 are implemented by CPU 45 in FIG. 5 executing a program stored in HDD 46 or memory 44 in FIG. 5.

Similarly, fault point locating server 200 shown in FIG. 4 can also be implemented as follows using computer system 40. Specifically, the functions of communication unit 210 in FIG. 4 are implemented by CPU 45 and network I/F 43 in FIG. 5. The functions of storage unit 220 can be implemented using a partial area of HDD 46 in FIG. 5. The functions of input accepting unit 230 in FIG. 4 can be implemented using input unit 42 and display 41 in FIG. 5. Display 41 can be used to display the input result to users.

The functions of training data generating unit 240, arc resistance computing unit 250, statistical model generating unit 260, and learning model generating unit 270 in FIG. 4 are implemented by CPU 45 in FIG. 5 executing a program stored in HDD 46 or memory 44.

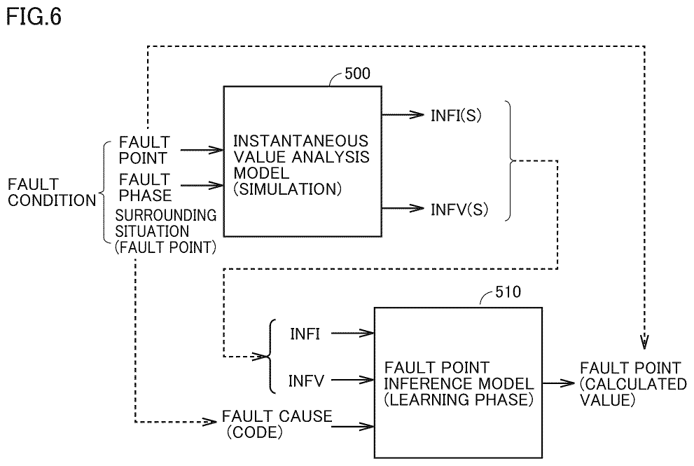

Referring now to FIG. 6 to FIG. 8, the fault point inference model and the statistical model will be described.

FIG. 6 shows the input-output relation in the learning phase of the fault point inference model.

Fault point inference model 510 is configured to receive input of current information INFI and voltage information INFV at the time of fault occurrence at CT (current transformer) or VT(voltage transformer) in electric power station 10 and the fault cause and output the fault point estimation result. Here, it is assumed that the fault point estimation result by machine learning using a regression approach is represented by a combination of the power transmission path and the distance from electric power station 10 on power system 5. Fault point inference model 510 corresponds to an example of “first inference model”.

The fault cause can be input to fault point inference model 510 as a fault cause code in multiple bits in which one-bit code is given to each of a plurality of causes (lightning, trees contact, birds and animals contact, metal contact, etc.) and “1: possible” or “0: no possible” is set for each bit. For example, the fault cause code may be defined such that the first bit is associated with the possibility of “lightning”, the second bit with the possibility of “trees contact”, and the third bit with the possibility of “birds and animals contact” in sequence from the right. In this case, when there is a possibility of lightning and trees contact and there is no possibility of birds and animals contact, fault cause code “011” is input.

In the learning phase of fault point inference model 510, the simulation result by instantaneous value analysis model 500 that reflects system information (the topology and impedance of power system 5) is used as training data (teacher data) for machine learning. Specifically, in order to generate training data, current and voltage (calculated values) at CT and VT in electric power station 10 in the event of a fault at a fault point under each fault condition are simulated on instantaneous value analysis model 500 under various fault conditions (fault point and fault phase). Based on the current and voltage (calculated values), current information INFI(S) and voltage information INFV(S) are acquired as simulation values. In this simulation, arc resistance is not taken into consideration, and current and voltage (calculated values) at CT and VT in electric power station 10 with arc resistance value =0 under each fault condition (fault point) are determined. As the fault cause under each fault condition, a cause presumable (possible) from the surrounding situation at the corresponding fault point can be set.

The fault phase includes one-phase ground fault (A phase ground fault, B phase ground fault, C phase ground fault), interphase short circuit (short circuit between A and B phases, short circuit between B and C phases, short circuit between C and A phases), two-phase ground fault (AB phase ground fault, BC phase ground fault, CA phase ground fault), three-phase short circuit, and three-phase ground fault. Since the above current information and the voltage increasing behavior vary for each fault phase, the simulation values by instantaneous value analysis model 500, that is, current information INFI(S) and voltage information INFV(S) vary. The fault phase of the system fault that has occurred can be identified from the measurement values (that is, current and voltage (actual values)) by CT and VT in electric power station 10 after system fault occurrence.

As indicated by the dotted lines in FIG. 6, current information INFI(S) and voltage information INFV(S) corresponding to current and voltage (calculated values) obtained by simulation are teacher data of current information INFI and voltage information INFV which are features (inputs) of fault point inference model 510. Further, teacher data of the fault cause (fault cause code) which is the feature (input) of fault point inference model 510 is created corresponding to the surrounding situation of the fault point under each fault condition. The fault point under each fault condition serves as teacher data of the fault point (calculated value) which is the answer (output) to the feature (input) of fault point inference model 510. The machine learning of fault point inference model 510 is performed using a set of these teacher data created for each fault condition.

As described above, since the current information and the voltage increasing behavior vary for each fault phase, fault point inference model 510 is created for each fault phase. On the other hand, since the fault phase that has occurred can be identified from current and voltage (actual values), fault point inference model 510 created for each fault phase can be uniquely selected at the time of inference. The fault phase therefore is not necessarily included in the features (inputs) of fault point inference model 510.

In fault point locating server 200, when fault point inference model 510 (for each fault phase) is acquired as the trained model as the result of the machine learning, data for representing the trained model is stored as calculation data 228 in storage unit 220. Further, data for representing the trained model (calculation data 228) is transmitted to fault point locater 100 through communication network 50 and stored as model information 121 in storage unit 120.

In fault point locater 100, location result inferring unit 140 can output the fault point location result by inference using the trained model, that is, fault point inference model 510 (trained model) for the fault phase that has occurred, at the time of system fault occurrence. In fault point location (inference phase), for input to fault point inference model 510 (trained), current information INFI and voltage information INFV are current and voltage (actual values) acquired at the time of system fault occurrence, and the fault cause code is a binary code set according to estimated fault cause CAest by fault cause estimator 150. As a result, the fault point (calculated value) indicated by the power transmission path and the distance from electric power station 10 is output from fault point inference model 510 (trained).

The introduction of the fault cause code enables the inference considering a surrounding situation for each spot in power system 5, that is, each candidate point of the fault point. For example, in the inference based only on impedance as in the comparative example in FIG. 1, both PFI in the forest and PF2 in the plain are calculated as candidate points and it is difficult to identify which of them is the fault point, whereas machine learning using the fault cause corresponding to the surrounding situation for each spot on power system 5 can provide the fault point location result additionally considering the surrounding situation. This inference can generate a fault point location result by solving the technical problem that it is difficult to identify a fault point from a plurality of candidate points that are equivalent in terms of impedance (electrical distance) as pointed out in the comparative example in FIG. 1. In doing so, the fault point location result can be represented by the fault point candidate and the probability of existence of fault point at each candidate.

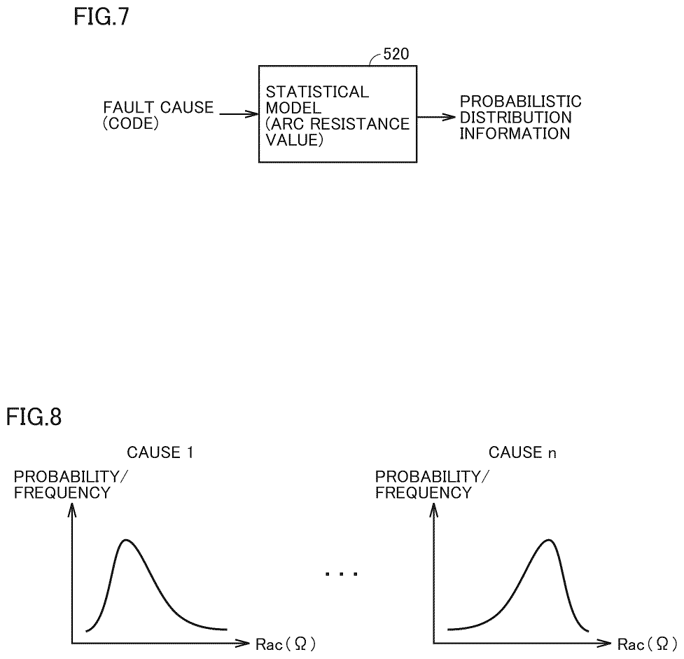

The arc resistance value statistical model will now be described. FIG. 7 shows a block diagram illustrating input/output of the statistical model, and FIG. 8 shows an output example of the statistical model. As described above, the probability distribution of arc resistance value takes different values mainly depending on the fault cause, whereas the difference due to the difference in fault point is relatively small.

Therefore, as shown in FIG. 7, statistical model 520 of arc resistance value is configured to receive input of a fault cause and output a histogram, a probability density function, a probability distribution function, a cumulative distribution function, or the like for representing the probabilistic distribution of arc resistance value. In generation of statistical model 520 (learning phase), the arc resistance value (calculated value) is calculated for each fault case, using current and voltage (actual values) acquired at the time of system fault occurrence in the past and information on the topology and impedance of power system 5. Specifically, the arc resistance value (calculated value) is calculated by arc resistance computing unit 250 of fault point locating server 200 shown in FIG. 4. Then, the arc resistance value (calculated value) is collected for each fault cause and subjected to statistical processing to generate statistical model 520 of arc resistance value. Specifically, statistical model 520 is generated by statistical model generating unit 260 of fault point locating server 200 shown in FIG. 4.

For example, as shown in FIG. 8, statistical model 520 of arc resistance value is constructed such that the probabilistic distribution of arc resistance value Rac is output for each of n fault causes (where n is a natural number). In the example in FIG. 8, for cause 1 (for example, metal contact), arc resistance value Rac is distributed in a relatively low region, and for cause n (for example, trees contact), arc resistance value Rac is distributed in a relatively high region.

For example, in fault point locating server 200, when statistical model 520 of the arc resistance value is generated, data for representing the statistical model is stored as calculation data 228 in storage unit 220. Further, data for representing the statistical model (calculation data 228) is transmitted to fault point locater 100 through communication network 50 and stored as model information 121 in storage unit 120.

In fault point locater 100, at the time of system fault occurrence, a fault cause code set according to estimated fault cause CAest by fault cause estimator 150 is input to statistical model 520. Thus, the probabilistic distribution of arc resistance value corresponding to the fault cause estimated by fault cause estimator 150 can be obtained as the output of statistical model 520. Specifically, the probabilistic distribution is acquired by location result inferring unit 140 of fault point locater 100 shown in FIG. 3.

As described above, the fault point (calculated value) output from fault point inference model 510 is obtained from the trained model using the simulation result with an arc resistance value of 0, while current information and voltage information (current and voltage (actual values)) at the time of fault occurrence include the influence of the arc resistance value. The fault point location result from fault point inference model 510 therefore may include an error resulting from the arc resistance value.

In the first embodiment, therefore, the accuracy of the fault point location result is improved by combining the fault point location result by fault point inference model 510 (trained model) with the arc resistance value (probabilistic distribution) estimated by statistical model 520.

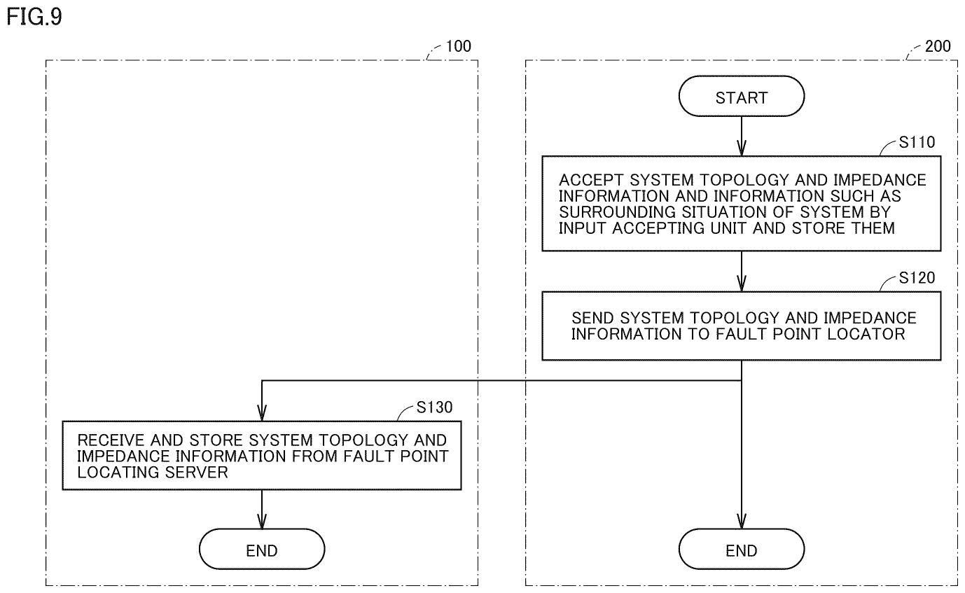

Referring now to FIG. 9 to FIG. 12, the process flow of fault point locater 100 and fault point locating server 200 will be described.

FIG. 9 is a flowchart illustrating the process of inputting and storing system information.

Referring to FIG. 9, at step (hereinafter simply denoted as “S”) 110, by input accepting unit 230 (FIG. 4), fault point locating server 200 accepts input of information on the system topology and impedance and information on the surrounding situation for power system 5 and stores them as system information 222 into storage unit 220 (FIG. 4).

Further, at S120, by communication unit 210, fault point locating server 200 sends the information on the system topology and impedance, among system information 222 stored into storage unit 220 at S110, to fault point locater 100 through communication network 50.

In response, at S130, fault point locater 100 receives the information on the system topology and impedance sent by fault point locating server 200 at S120 and stores it as system information 122 into storage unit 120 (FIG. 3). In the process in FIG. 9, the information on the system topology and impedance for power system 5 is stored in both of fault point locating server 200 and fault point locater 100. The information on the system surrounding situation for power system 5 is stored in fault point locating server 200. The process at S130 is performed by communication unit 110 (FIG. 3).

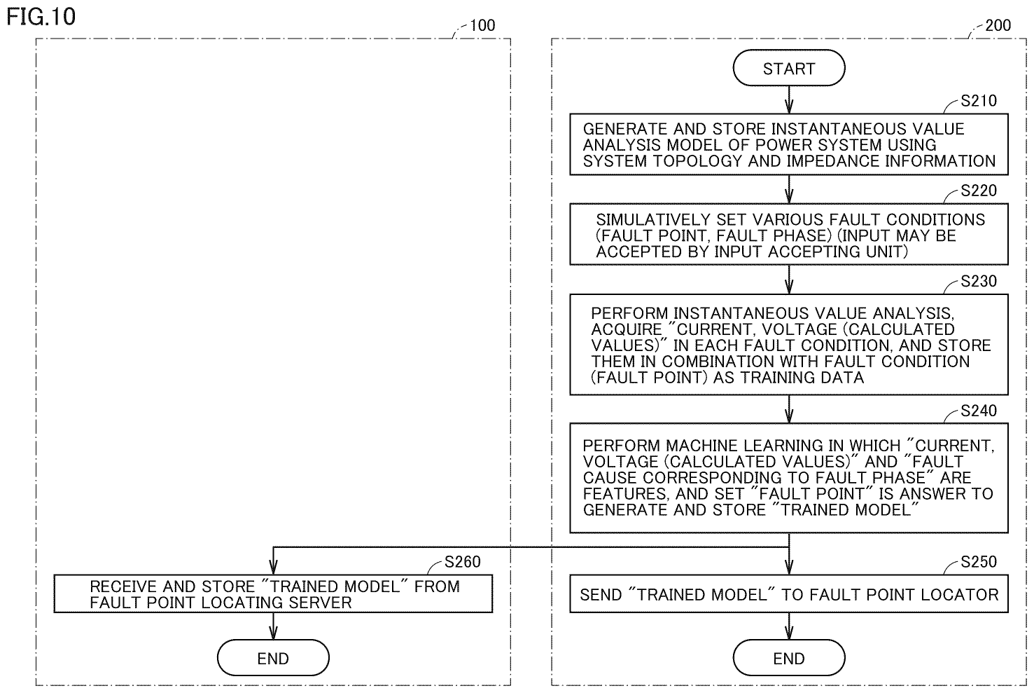

FIG. 10 is a flowchart illustrating the process of generating and storing training data and a trained model for fault point inference model 510 and a trained model.

Referring to FIG. 10, at S210, by training data generating unit 240, fault point locating server 200 generates instantaneous value analysis model 500 (FIG. 6) of power system 5, using the information on the system topology and impedance for power system 5 among system information 222 stored at S110 (FIG. 9). Then, at S220, by training data generating unit 240, fault point locating server 200 sets various fault conditions (fault point, fault phase, fault cause), which are input to instantaneous value analysis model 500 generated at S210. The fault cause under each fault condition reflects the surrounding situation of the corresponding fault point. As described above, although the fault cause can be set by the fault cause code represented in binary as described above, the fault cause may be set by a method different from this example.

As the fault phase, at least one of the phases included in one-phase ground fault, interphase short circuit, two-phase ground fault, three-phase short circuit, three-phase ground fault, and the like is set successively for each fault point. These fault conditions may be set (generated) automatically by training data generating unit 240 or may be input from the outside of fault point locating server 200 by input accepting unit 230.

At S230, by training data generating unit 240, fault point locating server 200 executes simulation calculation of calculating current data and voltage data at VT(15) and CT(11, 12) for each fault point under various fault conditions set at S220, on instantaneous value analysis model 500 generated at S210. The calculated values of current and voltage (simulation result) obtained under each fault condition are stored in combination with the fault condition (fault point, fault phase, fault cause) as training data.

At S240, by learning model generating unit 270, fault point locating server 200 executes machine learning described with reference to FIG. 6 using the training data obtained at S230. Specifically, supervised machine learning is performed on fault point inference model 510 for each fault phase, where the current and voltage (calculated values) and the fault cause, which are the simulation result under the fault condition of the corresponding fault phase, are “features (that is, input to fault point inference model 510)”, and the fault point under the corresponding fault condition (the fault point set (simulated) as a fault condition during instantaneous value analysis or the fault section including the fault point) is “answer (that is, output from fault point inference model 510)”. Through the machine learning, at S240, a trained model of fault point inference model 510 for each fault phase is generated. Data for representing the trained model is stored as calculation data 228 in storage unit 220.

At S250, by communication unit 210, fault point locating server 200 sends the data for representing the trained model stored in storage unit 220 at S240 to fault point locater 100 through communication network 50.

In response, at S260, by communication unit 110, fault point locater 100 receives the data for representing the trained model sent by fault point locating server 200 at S250. The received data is stored as model information 121 in storage unit 120 (FIG. 3).

In the process in fault point locating server 200 shown in FIG. 10, the process at S210 to S230 is performed by training data generating unit 240 in FIG. 4, the process at S240 is performed by learning model generating unit 270 in FIG. 4, and the process at S250 is performed by communication unit 210. S260 which is the process in fault point locater 100 is performed by communication unit 110 in FIG. 3.

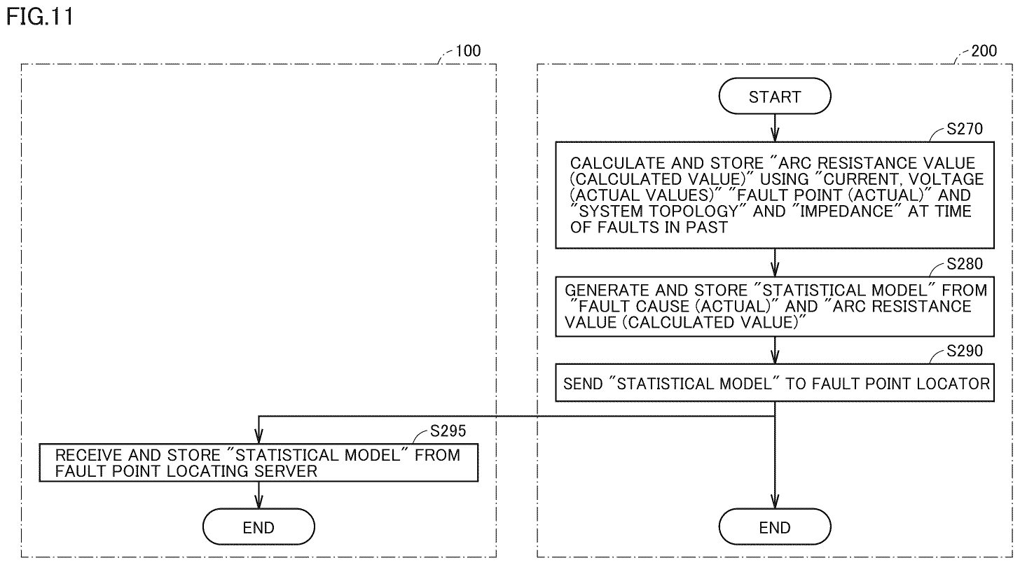

FIG. 11 is a flowchart illustrating the process of generating and storing statistical model 520.

Referring to FIG. 11, at S270, by arc resistance computing unit 250, fault point locating server 200 calculates the arc resistance value (calculated value) in each fault, using the current and voltage (actual values) and the fault cause (actual) recorded in fault-related information 226 in storage unit 220 and information on the topology and impedance of power system 5 recorded in system information 222 of storage unit 220, for each of a plurality of system faults in the past. The calculated arc resistance value is stored as fault-related information 226 in storage unit 220.

At S280, by statistical model generating unit 260, fault point locating server 200 generates statistical model 520 described with reference to FIG. 7 and FIG. 8 from the fault cause and the arc resistance value (calculated value) obtained at S270. Data for representing the generated statistical model 520 is stored as calculation data 228 in storage unit 220. The actual one is basically used as the fault cause but the estimation result may be used.

As described above, data for representing the statistical model includes, for example, a histogram, or a probability density function, a probability distribution function, a cumulative distribution function, or the like obtained from the histogram using a parametric approach (for example, the least square method may be employed but any method may be used) or a non-parametric approach (for example, the kernel density estimation method may be used but any method may be used).

At S290, by communication unit 210, fault point locating server 200 sends the data for representing the statistical model stored in storage unit 220 at S280 to fault point locater 100 through communication network 50.

In response, at S295, by communication unit 110, fault point locater 100 receives the data for representing the statistical model sent by fault point locating server 200 at S290. The received data is stored as model information 121 in storage unit 120.

In the process in fault point locating server 200 shown in FIG. 11, the process at S270 is performed by arc resistance computing unit 250 in FIG. 4, the process at S280 is performed by statistical model generating unit 260 in FIG. 4, and the process at S290 is performed by communication unit 210. S295 which is the process in fault point locater 100 is performed by communication unit 110 in FIG. 3.

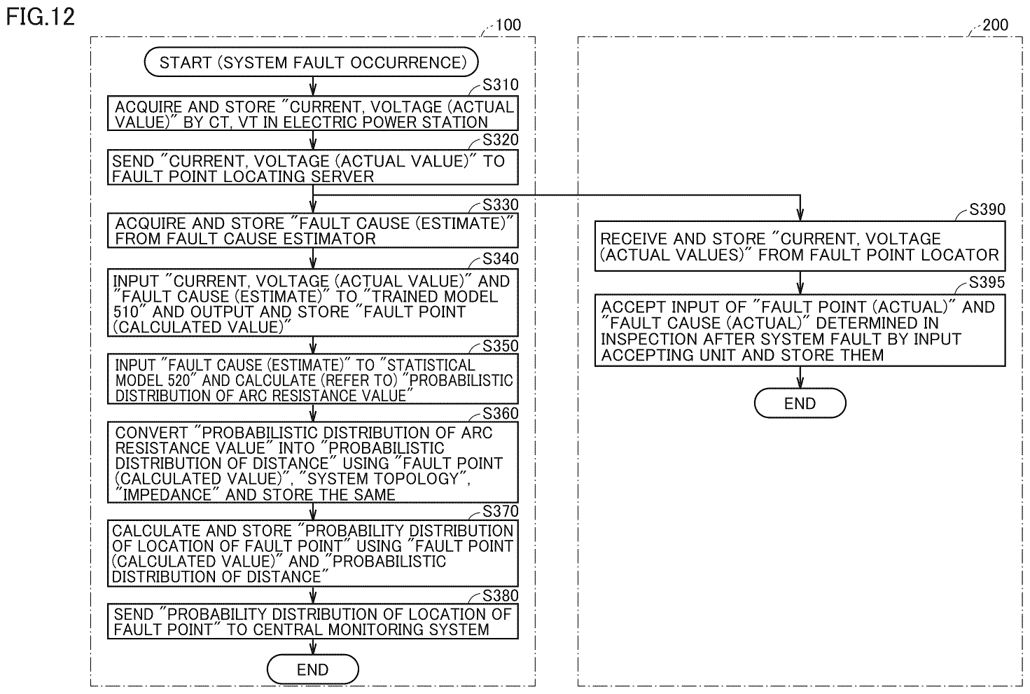

FIG. 12 is a flowchart illustrating the process for fault point location at the time of system fault occurrence in the fault point locating system according to the first embodiment. The process shown in FIG. 12 is started when fault point locater 100 detects a fault occurrence in power system 5. A fault occurrence may be detected by fault point locater 100 acquiring and monitoring current and voltage (actual values) measured by CT(11, 12) and VT(15) in electric power station 10 or may be detected by receiving a trip signal from a not-shown system protecting relay separately installed in electric power station 10. Alternatively, the operator at the control center having central monitoring system 300 may manually detect a fault occurrence through communication network 50, that is, may manually externally start fault point locater 100 to perform the operation in FIG. 12.

Referring to FIG. 12, at S310, by data acquisition unit 130, fault point locater 100 acquires current and voltage (actual values) at the time of fault occurrence that are measured by CT(11, 12) and VT(15) in electric power station 10. The acquired current and voltage (actual values) at the time of fault occurrence are stored as measurement data 124 in storage unit 120.

At S320, by communication unit 110, fault point locater 100 sends the current and voltage (actual values) at the time of fault occurrence stored at S310 to fault point locating server 200 through communication network 50. S320 may be performed at any time after fault occurrence and is not necessarily performed at the timing shown in the flowchart in FIG. 12. For example, a batch process may be performed during hours (for example, at night) when there is room in the processing ability of fault point locater 100 or fault point locating server 200 or the communication status of communication network 50.

In response, at S390, fault point locating server 200 receives the current and voltage (actual values) at the time of fault occurrence sent from fault point locater 100 at S320 by communication unit 210, and stores them as measurement data 224 into storage unit 220. S390 is also not necessarily performed at the timing shown in the flowchart in FIG. 12 and may be performed after fault point locater 100 performs S320.

Further, at S395, by input accepting unit 230, fault point locating server 200 accepts input of the fault point (actual) and the fault cause (actual) recognized in the inspection after the system fault and stores them as fault-related information 226 into storage unit 220. As described above, the fault point (actual) and the fault cause (actual) may be acquired by referring to a not-shown system fault-related database. S395 is also not necessarily performed at the timing shown in the flowchart in FIG. 12 and may be performed at any time after fault point locating server 200 performs S390. In this way, the processing timing of S320, S390, S395 is not limited to that in the flowchart in FIG. 12.

On the other hand, at S330, fault point locater 100 receives the fault cause estimation result (estimated fault cause CAest) from fault cause estimator 150 (FIG. 2) by communication unit 110, and stores it as fault cause estimation result 126 into storage unit 120. As described above, fault cause estimator 150 is provided separately from fault point locater 100 according to the present embodiment and, at the time of fault occurrence, operates in parallel with fault point locater 100 in response to input of current information and voltage information (current and voltage (actual values)) and outputs estimated fault cause CAest.

At S340, by location result inferring unit 140, fault point locater 100 inputs the current and voltage (actual values) at the time of fault occurrence acquired at S310 and the fault cause estimation result (estimated fault cause CAest) acquired at S330 to fault point inference model (trained model) 510 stored as model information 121. As described above, in doing so, fault point inference model 510 corresponding to the fault phase identified from current and voltage (actual values) is selected. The fault cause estimation result can be input to fault point inference model 510 as a binary code set according to estimated fault cause CAest.

The fault point (calculated value) is thus acquired as the output from fault point inference model (trained model) 510. The acquired fault point (calculated value) is stored as calculation data 128 in storage unit 120. As described above, the fault point (calculated value) which is an output value of fault point inference model 510 can be represented by a candidate for the fault point indicating a particular spot or a section on power system 5 and the probability of existence of fault point in each candidate. Assuming that the probability of existence is 100(%), one fault point (calculated value) may be determined.

At S350, by location result inferring unit 140, fault point locater 100 inputs the fault cause estimation result (estimated fault cause CAest) acquired at S330 to statistical model 520 stored as model information 121. Thus, the probabilistic distribution of arc resistance value corresponding to the fault cause (estimation result) is acquired as output of statistical model 520.

At S360, by location result inferring unit 140, fault point locater 100 calculates a probabilistic distribution of distance by performing distance conversion of the probabilistic distribution of arc resistance value acquired at S350, considering the actual impedance of the power transmission line and the like. Specifically, considering the topology and impedance of a system (power transmission line, power distribution line, etc.) present before and after the fault point (calculated value) determined at S340, the probabilistic distribution of arc resistance value acquired at S350 is converted into the probabilistic distribution of distance. In doing so, the arc resistance value can be converted into the distance on the path from the fault point (calculated value) by identifying the impedance of power transmission line, power distribution line, or the like around the fault point (calculated value) from the information on topology and impedance of power system 5 (system information 122 in storage unit 120). The acquired probabilistic distribution of distance is stored as calculation data 128 in storage unit 120.

At S370, by location result inferring unit 140, fault point locater 100 calculates the probability distribution of the location of fault point as fault point location result PFrst, using the fault point (calculated value) acquired at S340 and the probabilistic distribution of distance obtained at S360. Fault point location result PFrst calculated at S370 is stored as calculation data 128 in storage unit 120.

FIG. 13 is a block diagram illustrating fault point location according to the first embodiment. The functions in the block diagram in FIG. 13 are implemented by the process at S340 to S370 in FIG. 12.

Referring to FIG. 13, the trained fault point inference model 510 receives current information INFI and voltage information INFV which are current and voltage (actual values) at the time of fault occurrence and the fault cause (estimated fault cause CAest) and outputs fault point PF0, in the process at S340. Fault point PF0 corresponds to the fault point (calculated value) described above. When fault point PF0 indicates a spot on power system 5, fault point PF0 is identified by the power transmission path and the distance from electric power station 10. Fault point PF0 may be identified as one section including the fault point, among a plurality of sections into which a power transmission line and a power distribution line in power system 5 are divided in advance. For example, fault point PF0 corresponds to the one that fault point inference model 510 infers as one spot where the probability of existence of fault point on power system 5 is the largest.

Alternatively, fault point inference model 510 may output fault point PF0 such that a plurality of spots on different paths from electric power station 10 are included. In this case, for a plurality of spots, the calculated value of the probability of existence of fault point is inferred in accordance with a combination of the fault cause estimation result (estimated fault cause CAest) and the surrounding situation of each of a plurality of spots. Specifically, the probability of existence of fault point is distributed among a plurality of spots, where the sum of probability of existence of fault point at each of the spots included in fault point PF0 is 1.0. For example, in the example in FIG. 1, when the fault cause estimation result (estimated fault cause CAest) indicates “trees contact”, both spots PF1 and PF2 may be given the probability of existence of fault point as fault point PF0 and then output from fault point inference model 510. In this example, the inference result is such that the probability of existence of fault point at spot PF1 (for example, 80(%)) is higher than the probability of existence at spot PF2 (for example, 20(%)).

In the process at S350, statistical model 520 of arc resistance value receives the fault cause (estimated fault cause CAest) and outputs the probabilistic distribution Rac(0) of arc resistance value corresponding to the fault cause (estimation result). Probabilistic distribution Rac(0) can be represented by the histogram, probability density function, probability distribution function, cumulative distribution function or the like of arc resistance value Rac, as described with reference to FIG. 8.

An integration processing unit 530 receives fault point PF0 from fault point inference model 510 and probabilistic distribution Rac(0) of arc resistance value from statistical model 520. Integration processing unit 530 converts arc resistance value Rac into the distance from fault point PF0 on the power transmission path including fault point PF0, using the topology and impedance of the surrounding power transmission line, power distribution line, and the like around fault point PF0. Thus, in the process at S360, probabilistic distribution Rac(0) of arc resistance value is converted into a probabilistic distribution of the distance between fault point PF0 and the actual fault point corresponding to the arc resistance value.

In the process at S370, integration processing unit 530 further outputs fault point location result PFrst, using fault point PF0 and the probabilistic distribution of the distance between fault point PF0 and the actual fault point.

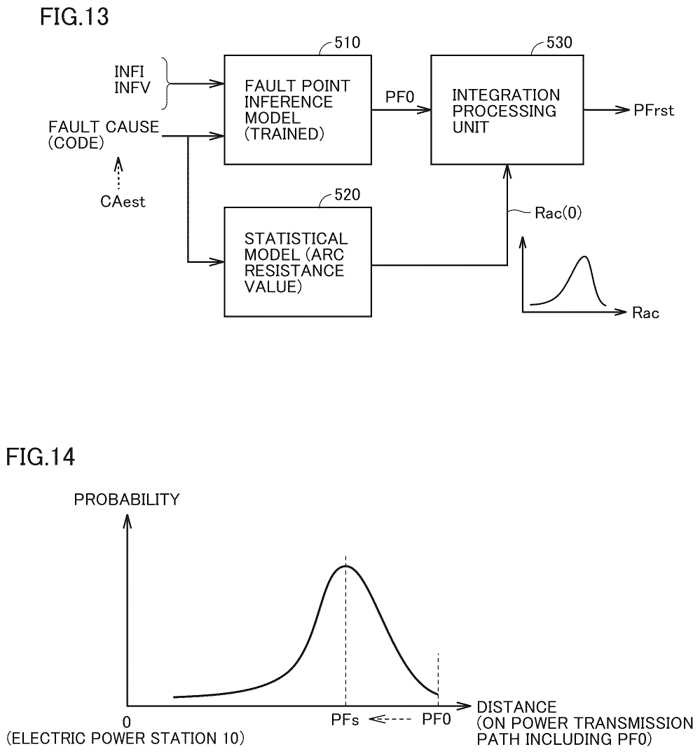

FIG. 14 is a conceptual diagram illustrating an output example of fault point location result PFrst.

As shown in FIG. 14, as an example, fault point location result PFrst is indicated as a probability distribution of the location of fault point, at each spot on the power transmission path from electric power station 10 that is identified to indicate fault point PF0.

In the example in FIG. 14, since the probabilistic distribution of the distance corresponding to the arc resistance value is reflected, the probability of existence of fault point is the largest at spot PFs different from the spot corresponding to fault point PF0. That is, the spot where the probability of existence of fault point is the largest on power system 5 is corrected from the output of fault point inference model 510, in accordance with the estimated arc resistance value. Therefore, compared to the fault point location result only by fault point inference model 510, the location accuracy can be improved by combining the estimation of arc resistance value from the fault cause (estimated fault cause CAest).

For example, when one fault point PF0 is output from fault point inference model 510, the probability of existence of fault point at each spot around fault point PF0 is equivalent to the probabilistic distribution of distance corresponding to the arc resistance value.

On the other hand, when a plurality of fault points PF0 are given the probability of existence of fault point and output from fault point inference model 510, for the probability of existence of fault point at each spot around each of fault points PF0, fault point location result PFrst can be obtained by multiplying the probabilistic distribution of arc resistance value (distance) by the probability of existence of fault point at the fault point PF0.

When fault point PF0 specifies one section including the fault point among a plurality of sections divided in advance in power system 5, fault point location result PFrst can be indicated as the probability of existence of fault point at each of a plurality of sections. Also in this case, the section including fault point PF0 is indicated as one spot inferred by fault point inference model 510 where the probability of existence of fault point is the largest on power system 5. However, by reflecting the probabilistic distribution of distance corresponding to the arc resistance value, the probability of existence of fault point is the largest in a section different from the section including fault point PF0.

In this way, in order to consider the influence by the arc resistance value that varies with fault causes, fault point location result PFrst is generated in such a manner as to be corrected by the arc resistance value obtained by statistical model 520, based on fault point PF0 from fault point inference model 510.

Referring to FIG. 12 again, at S380, by communication unit 110, fault point locater 100 sends the probability distribution of the location of the fault point (fault point location result PFrst) acquired at S370 to central monitoring system 300 through communication network 50. Central monitoring system 300 corresponds to an example of “manned facility”.

Thus, in central monitoring system 300, maintenance workers are provided with fault point information represented by fault point location result PFrst that indicates the probability distribution of the location of fault point, thereby expediting identification of the fault point and finding of the cause by inspection by maintenance workers as well as subsequent recovery work. The fault point information may be provided such that the fault point estimation result is visually displayed on the topology of power system 5.

As explained above, according to the first embodiment, fault point location is performed with additional input of the fault cause (estimated fault cause CAest), whereby the location result (fault point location result PFrst) that quantifies the probability of existence of fault point can be obtained by combining extraction of a plurality of spots with equivalent electrical distances (impedance) from electric power station 10 to the fault point with inference that reflects the relation between the fault cause (estimated fault cause CAest) and the surrounding situation at each spot. The fault point location result can be narrowed down so as to indicate a single spot where the existence of fault point is largest, according to the quantified probability of existence.

In this way, the present embodiment can increase the accuracy in locating a fault point, while the comparative example described with reference to FIG. 1 fails to find the quantified probability of existence of fault point for each of spots PF1 and PF2. For example, identification of one of spots PF1 and PF2 in FIG. 1 (that is, the location in which the probability of existence is quantified as 100 (%)) can be achieved.

Alternatively, for both of spots PF1 and PF2 in FIG. 1, the location result including a plurality of fault points (fault point location result PFrst) can be obtained together with the quantified probability of occurrence of fault points in accordance with a combination of the fault cause estimation result (estimated fault cause CAest) and the surrounding situation.

Specifically, in the learning phase of fault point inference model 510, machine learning including, as teacher data, the fault point assumed by simulation and the fault cause that reflects the surrounding situation of the fault point is performed to generate a trained model capable of inference with the above combination.

In addition, fault point location is in such a manner that reflects the distance on power system 5 that corresponds to the arc resistance value varying with a fault cause, based on the fault point (calculated value) calculated by fault point inference model 510. This manner of fault location can increase the location accuracy, compared to the fault point location only by fault point inference model 510, as explained in the example in FIG. 14.

In addition, the probability of existence of fault point is determined as a fault point location result using the probabilistic distribution of arc resistance value by statistical model 520. This can lead to efficient inspection after a fault by maintenance workers and reduction in inspection time. For example, when it is found that no fault point exists at a spot or section where the probability of existence is the largest, the next spot (section) to inspect or the direction to inspect for fault point search can be determined in accordance with the probability distribution. This can lead to efficient search operation for the fault point.

The improvement in fault point location accuracy in this manner can lead to reduction in man power and cost for fault search as well as improvement in power quality because of reduction in fault recovery time (blackout duration). Furthermore, efficient maintenance and conservation of power system 5 can be achieved.

### Modification of First Embodiment

In the first embodiment, it is assumed that current and voltage measured by voltage transformer (VT) and current transformer (CT) are used as they are, for current information INFI and voltage information INFV which are features input to fault point inference model 510. On the other hand, in a modification described below, processed data obtained by calculation from the current and voltage is also included in current information INFI and voltage information INFV.

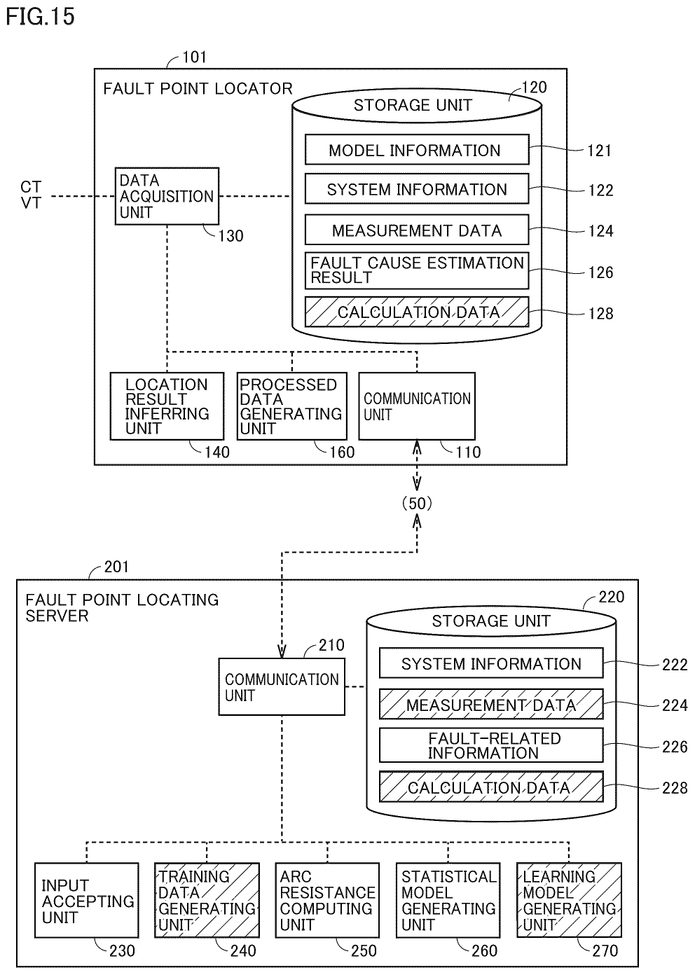

FIG. 15 is a block diagram illustrating a configuration example of a fault point locater 101 according to a modification of the first embodiment.

As shown in FIG. 15, fault point locater 101 according to a modification of the first embodiment differs from fault point locater 100 (FIG. 3) according to the first embodiment in that it further includes a processed data generating unit 160.

Processed data generating unit 160 calculates processed data using current and voltage (actual values) by current transformer (CT) and voltage transformer (VT) that are received by communication unit 110. The processed data includes, for example, total harmonic distortion plus noise, third harmonic contents, crest factor, maximum, variation in a certain period, frequency component analysis result, impedance value, current change rate before and after fault, and voltage change rate before and after fault. The processed data (actual value) calculated by processed data generating unit 160 is stored as calculation data 128 in storage unit 220.

At the time of fault occurrence, the processed data (actual value) calculated by processed data generating unit 160 is stored in storage unit 220 and sent by communication unit 110 to a fault point locating server 201 according to the modification of the first embodiment through communication network 50.

In fault point locating server 201, current information INFI and voltage information INFV before and after the fault including those at the time of fault occurrence received by communication unit 210 are stored as measurement data 224 in storage unit 220, in the same manner as in the first embodiment. Specifically, in the modification of the first embodiment, measurement data 224 stored in storage unit 220 includes the processed data (actual value) calculated by processed data generating unit 160 in addition to current and voltage (actual values) similar to those in the first embodiment.

Further, in fault point locating server 201 according to the modification of the first embodiment, training data generating unit 240 includes a calculation function similar to processed data generating unit 160. Training data generating unit 240 adds, to training data, processed data (calculated value) acquired by the calculation function similar to processed data generating unit 160 from the current and voltage (calculated values) at CT and VT in electric power station 10 obtained as output of instantaneous value analysis model 500 (FIG. 6).

Thus, in the modification of the first embodiment, for each simulated fault, a set of the fault point, the corresponding current data and voltage data (calculated values) before and after the fault, and the processed data (calculated value) is used as training data for use in machine learning and stored as calculation data 228 in storage unit 220. It is not necessary to use all of the corresponding current data and voltage data (calculated value) before and after the fault, and the processed data (calculated value) as training data. Among these, at least one quantity may be used as a feature or a plurality of quantities may be used as features.

In the learning phase of fault point inference model 510, machine learning using training data (teacher data) is performed in such a manner that the items of current information INFI(S) and voltage information INFV(S) which are training data are increased by adding the processed data (calculated value). Thus, learning model generating unit 270 can generate the trained fault point inference model 510 in which the input features are current and voltage (actual values) similar to those in the first embodiment and the processed data (actual value) as the additional item. As described above, it is not necessary to use all of the corresponding current data and voltage data (calculated value) before and after the fault, and the processed data (calculated value) as training data. Among these, at least one quantity may be used as a feature or a plurality of quantities may be used as features. Data for representing the trained model is stored as calculation data 228 in storage unit 220 and transmitted to fault point locater 101 through communication network 50 and stored as model information 121 in storage unit 120.

In fault point locater 101 according to the modification of the first embodiment, at the time of fault occurrence, current information INFI and voltage information INFV including the current and voltage (actual values) before and after the fault and the processed data (actual value), and estimated fault cause CAest by fault cause estimator 150 are input to the trained fault point inference model 510.

Fault point PF0 similar to that in the first embodiment can then be output from fault point inference model 510 as the fault point estimation result indicating one spot or one section on power system 5. The other process in fault point location is similar to that of the first embodiment and will not be further elaborated.

Adding the data processed values based on current and voltage to the current information and voltage information which are input values to fault point inference model 510 can be expected to improve the accuracy in locating a fault point.

In the first embodiment, training data for use in the learning phase of fault point inference model 510 is constructed with simulation values using instantaneous value analysis model 500. However, training data may be constructed not only with simulation values but also with current and voltage (actual values) before and after the fault at the time of fault occurrence that are stored as measurement data 224, or current and voltage (actual values) and processed data (actual value), in addition to the simulation values.

In this way, creating the trained fault point inference model 510 by machine learning using both simulation values and actual values can be expected to improve the accuracy in locating a fault point.

Alternatively, system information 222 can be corrected using at least one of current and voltage (actual values) before and after the fault and the processed data (actual value). In particular, it is expected that correcting the impedance information, which tends to contain many errors, has a noticeable effect. Thus, improvement in accuracy of simulation by instantaneous value analysis model 500 can be expected to improve the accuracy of estimation by fault point inference model 510 and then improve the accuracy in locating a fault point.

### Second Embodiment

A modification of the fault point inference model will now be described. In the following embodiment, the operation and function of training data generating unit 240 and learning model generating unit 270 (fault point locating server 200) in the learning phase and the operation and function of location result inferring unit 140 (fault point locater 100) during fault point location (inference phase) are modified as appropriate in accordance with the content of the modified fault point inference model.

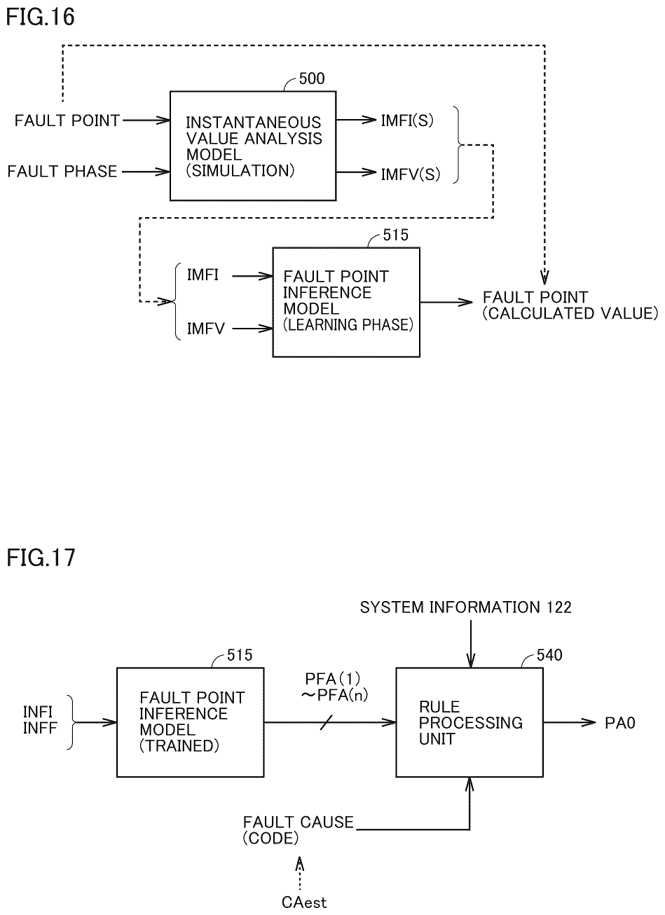

FIG. 16 is a block diagram illustrating input/output in the learning phase of the fault point inference model in a second embodiment.

Referring to FIG. 16, a fault point inference model 515 according to the second embodiment is configured to receive input of current information INFI and voltage information INFV and output the fault point estimation result. In other words, fault point inference model 515 differs from fault point inference model 510 according to the first embodiment in that the fault cause is eliminated from input.

In the learning phase of fault point inference model 515, instantaneous value analysis model 500 which reflects system information (topology and impedance of power system 5) performs simulation similar to that of the first embodiment and outputs current and voltage (calculated values) at CT and VT in electric power station 10 in the event of a system fault under each of various fault conditions (fault point and fault phase) set for generating training data. Current information INFI(S) and voltage information INFV(S) are thus acquired as simulation values based on the current and voltage (calculated values).

As indicated by the dotted lines in FIG. 16, in the learning phase, training data generating unit 240 of fault point locating server 200 shown in FIG. 4 generates teacher data in which current information INFI(S) and voltage information INFV(S) which are simulation values are the input (features) of fault point inference model 515 and the fault point in simulation is the output (answer) of fault point inference model 515. Through machine learning using the generated training data (teacher data), learning model generating unit 270 of fault point locating server 200 shown in FIG. 4 generates the trained fault point inference model 510 (learning model generating unit 270). In the second embodiment, the process at S230 and S240 in FIG. 10 is modified as appropriate in accordance with FIG. 16.

Also in the second embodiment, for each fault point, fault point inference model 510 is created for each fault phase using current information INFI(S) and voltage information INFV(S) obtained for each fault phase.

At the time of system fault occurrence, when selected in accordance with the fault phase that has occurred, fault point inference model 515 can output the calculated value of the fault point by inference using the trained model. In fault point location (inference phase), current information INFI and voltage information INFV for input to fault point inference model 510 (trained) are set to the values (actual values) acquired at the time of fault occurrence. The fault point (calculated value) indicated by a combination of the power transmission path and the distance from electric power station 10 is output from fault point inference model 515 (trained) in the same manner as in the first embodiment. Fault point inference model 515 corresponds to an example of “second inference model”.

However, fault point inference model 515 according to the second embodiment performs inference only based on the electrical distance (impedance) from electric power station 10 in the same manner as inference model 101M according to the comparative example. Therefore, when there are a plurality of spots with equivalent electrical distances (impedance) from electric power station 10 on power system 5, a plurality of fault points (calculated values) are calculated. For example, the fault point (calculated value) by fault point inference model 515 includes both spots PFI and PF2 assumed in the comparative example in FIG. 1. Unlike fault point inference model 510 in the first embodiment, the fault point (calculated value) calculated by fault point inference model 515 does not involve information indicating the probability of existence of fault point. In other words, when there are a plurality of fault points (calculated values) calculated by fault point inference model 515, the probability of existence of fault point is the same among a plurality of fault points, in this stage.

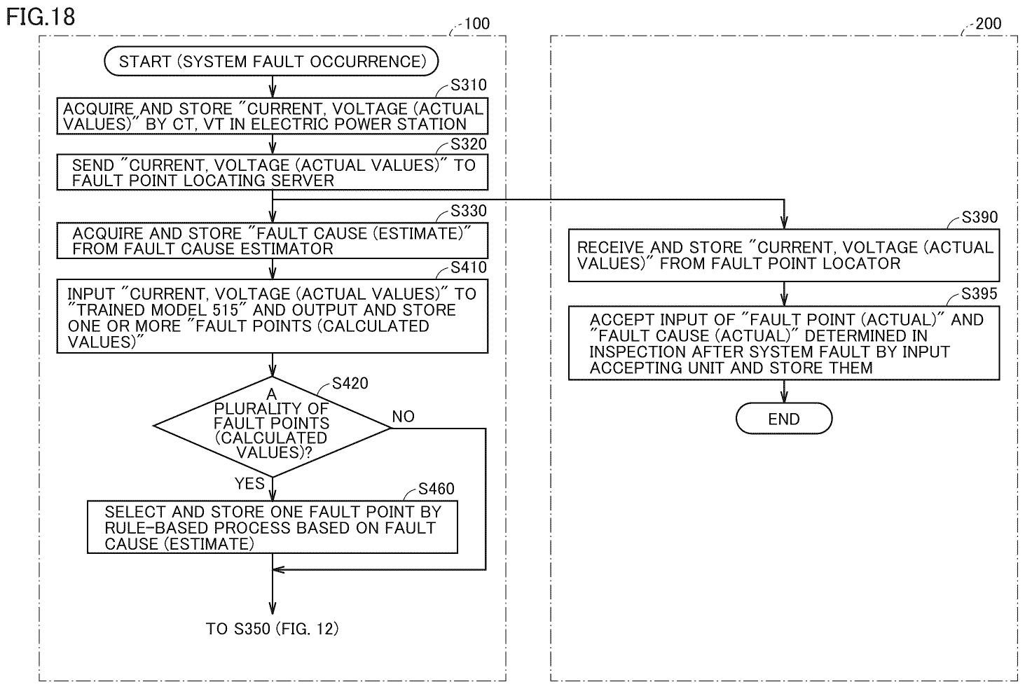

FIG. 17 is a block diagram illustrating calculation of the fault point in fault point location according to the second embodiment.

As shown in FIG. 17, in the second embodiment, the function equivalent to fault point inference model 510 according to the first embodiment is implemented by a combination of the trained fault point inference model 515 and a rule processing unit 540.

Referring to FIG. 17, the trained fault point inference model 515 receives current information INFI and voltage information INFV indicating current and voltage (actual values) at the time of fault occurrence and outputs one or more fault points PFA(1) to PFA(N) (where N is a natural number). Fault points PFA(1) to PFA(N) correspond to the above fault points (calculated values). Each of fault points PFA(1) to PFA(N) can be identified as the power transmission and the distance from electric power station 10 or one section among a plurality of sections into which the power transmission line and the power distribution line in power system 5 are divided in advance, in the same manner as fault point PF0 in the first embodiment.

Rule processing unit 540 receives fault points PFA(1) to PFA(N) output from fault point inference model 515, system information 122 (the surrounding situation at each spot in power system 5), and a fault cause (estimated fault cause CAest). The fault cause can be a fault cause code set in accordance with estimated fault cause CAest in the same manner as in the first embodiment. The surrounding situation at each of fault points PFA(1) to PFA(N) can be acquired using system information 122 (the surrounding situation at each spot in power system 5).

When there are a plurality of fault points PFA(1) to PFA(N) (that is, N≥2), rule processing unit 540 can select one fault point in accordance with a rule process preset for a combination of the surrounding situation of each of fault points PFA(1) to PFA(N) and the fault cause (for example, a combination of select logics or a machine learning process separate from generation of fault point inference model 515). As an example of the select logics, when the fault cause is “trees contact”, the fault point having the surrounding situation “plain” can be unselected. The rule process can be constructed as desired based on such predetermined select logics.

The fault point location results of a plurality of spots may be given the probability of existence of fault point and ranked, in consideration of the surrounding situation. In this case, the rule in rule processing unit 540 is determined to calculate the probability of existence of fault point at each of a plurality of fault points PFA(1) to PFA(N), rather than selecting one of a plurality of fault points PFA(1) to PFA(N) as described above. In particular, rule processing unit 540 can define a distribution rule of the probability of existence of fault point, rather than the select/unselect rule as a fault point, in accordance with a combination of the surrounding situation of each of a plurality of fault points PFA(1) to PFA(N) and a fault cause (estimated fault cause CAest), where the sum of probability of existence of fault point at fault points PFA(1) to PFA(N) is 1.0. Also in this case, the distribution rule in accordance with the combination can be defined as appropriate.

Thus, fault point PF0 can be output from rule processing unit 540 as information for indicating one spot or one section in power system 5 where the probability of existence of fault point is the largest, in the same manner as fault point inference model 510 according to the first embodiment. Alternatively, each of fault points PFA(1) to PFA(N) given the probability of existence of fault point can be output from rule processing unit 540. Therefore, in the configuration in FIG. 13, the fault point (calculated value) output from rule processing unit 540 can be used in the same manner as fault point PF0.

FIG. 18 is a flowchart illustrating the process for fault point location at the time of system fault occurrence in the fault point locating system according to the second embodiment.

Referring to FIG. 18, in the second embodiment, fault point locater 100 performs S310 and S320 similar to those in FIG. 12. As a result, current and voltage (actual values) measured at CT(11, 12) and VT(15) in electric power station 10 at the time of fault occurrence are acquired as current information INFI and voltage information

INFV at the time of a fault. The acquired current and voltage (actual values) are stored as measurement data 124 in storage unit 120 and sent to fault point locating server 200 through communication network 50. In fault point locating server 200, at S390 and S395 similar to those in FIG. 12, the current and voltage (actual values) at the time of fault occurrence are stored.

Further, the fault point locater receives and stores the fault cause estimation result (estimated fault cause CAest) from fault cause estimator 150 (FIG. 1), at S330 similar to that in FIG. 12, and inputs the current and voltage (actual values) at the time of fault occurrence acquired at S310 to the trained fault point inference model 515, at S410. As a result, fault points PFA(1) to PFA(N) in FIG. 17 are output as fault points (calculated values) (where N≥1) from fault point inference model 515.

At S420, fault point locater 100 determines whether a plurality of fault points (calculated values) are acquired at S410. If N≥2 (more than one) (YES at S420), at S430, one fault point (calculated value) is selected according to a predetermined rule, based on a combination of the fault cause (estimated fault cause CAest) and the surrounding situation at each of a plurality of fault points (calculated values). On the other hand, if N=1 (one) (NO at S420), the fault point (calculated value) acquired at S410 is set as it is as the final one fault point (calculated value). In other words, the process at S420 and S430 is implemented by the function of rule processing unit 540 in FIG. 17.

As a result, the fault point (calculated value) similar to that of S340 in FIG. 12 can be obtained. Therefore, fault point location result PFrst similar to that of the first embodiment can be obtained also in the second embodiment by performing the process subsequent to S350 in FIG. 12 after the process at S430 or after NO at S420. In other words, the fault point can be located with high accuracy by correcting the fault point (calculated value) obtained by fault point inference model 515 by the arc resistance value by statistical model 520.

In this way, in the fault point location according to the second embodiment, although the fault cause is not directly incorporated into teacher data for machine learning for generating fault point inference model 515, rule processing unit 540 can be used to achieve fault point location with additional input of the fault cause (estimated fault cause CAest), thereby achieving the same effects as in the first embodiment.

The modification of the first embodiment can also be applied to the second embodiment. In other words, the processed values of current and voltage may be added to current information and voltage information used in the learning phase and the inference phase of fault point inference model 515, and current and voltage (actual values) at the time of fault occurrence may be added to the training data used in the learning phase of fault point inference model 515. Further, system information 222 reflected in instantaneous value analysis model 500 may be corrected using the current and voltage (actual values) and/or the processed data (actual value).

In the first and second embodiments, the current and voltage (calculated values) and the current and voltage (actual values) at the time of fault occurrence are mainly used for current information INFI and voltage information INFV used in the learning phase and the inference phase of fault point inference models 510, 515. However, the current and voltage (calculated values) and the current and voltage (actual values) before fault occurrence and/or after fault occurrence can be further used in addition to those at the time of fault occurrence. For example, the current change rate before and after fault, the voltage change rate before and after fault, and the like described in the modification of the first embodiment can be used as input values in the learning phase and the inference phase of fault point inference models 510, 515. In this way, learning and inference using current information INFI and voltage information INFV in which the current behavior and voltage behavior before and after fault occurrence are reflected altogether can increase the accuracy in fault point location.

Although the embodiments of the present invention have been described, the embodiments disclosed here should be understood as being illustrative rather than being limitative in all respects. The scope of the present invention is shown in the claims, and it is intended that all modifications that come within the meaning and range of equivalence to the claims are embraced herc.

What is claimed is:

1. A fault point locater for a power system, comprising:
a data acquisition unit to acquire current information and voltage information at a predetermined spot at a time of fault occurrence; and
an inference unit to receive input of the current information and voltage information obtained by the data acquisition unit at the time of fault occurrence and an estimated fault cause based on the current information and voltage information, and to output a location result that quantifies a probability of existence of fault point on the power system.

2. The fault point locater according to claim 1, further comprising a storage unit to store a machine-trained first inference model receiving input of current information and voltage information at the predetermined spot and a fault cause and outputting a fault point calculated value indicating one spot or a plurality of spots inferred to be likely to be the fault point on the power system, wherein the fault cause reflecting a surrounding situation at each spot in the power system is set in the first inference model,
wherein the inference unit outputs the location result using the fault point calculated value when the current information and voltage information obtained by the data acquisition unit at the time of fault occurrence and the estimated fault cause based on the current information and voltage information are input to the first inference model.

3. The fault point locater according to claim 2, wherein the first inference model is machine-trained using: current information and voltage information at the predetermined spot at a time of simulated fault occurrence at a set supposed fault point that are calculated by a simulator to reflect information on topology and impedance of the power system, as teacher data of the current information and voltage information at the time of fault occurrence; a fault cause corresponding to the surrounding situation at the supposed fault point as teacher data of the fault cause; and the supposed fault point as teacher data of the fault point calculated value.

4. The fault point locater according to claim 2, wherein when the fault point calculated value including the plurality of spots is output, the first inference model outputs the fault point calculated value involving a calculated value of the probability of existence of fault point at each of the plurality of spots.

5. The fault point locater according to claim 2, wherein the first inference model outputs the fault point calculated value to indicate the one spot where the probability of existence of fault point is largest.

6. The fault point locater according to claim 2, wherein
the storage unit further stores a statistical model configured to, in response to input of the fault cause, output a probabilistic distribution of arc resistance value corresponding to the input fault cause, from the probabilistic distribution at the fault point that is predetermined for each fault cause using an actual value at a time of fault occurrence in the past,
the inference unit inputs the estimated fault cause to the statistical model at the time of fault occurrence, and
the inference unit includes an integration processing unit to integrate the fault point calculated value output from the first inference model and the probabilistic distribution of arc resistance value output from the statistical model and output a distribution of the probability of existence of fault point on the power system as the location result.

7. The fault point locater according to claim 1, further comprising a storage unit to store a machine-trained second inference model and second system information, the second inference model receiving input of current information and voltage information at the predetermined spot and outputting a fault point calculated value corresponding to one or more spots with an equivalent electrical distance from the predetermined spot, the second system information indicating a surrounding situation at each spot in the power system, wherein
the inference unit inputs to the second inference model the current information and voltage information obtained by the data acquisition unit at the time of fault occurrence and acquires the fault point calculated value,
the inference unit includes a rule processing unit to, when the fault point calculated value includes a plurality of spots, apply a predetermined rule to a combination of the surrounding situation of each of the plurality of spots indicated by the second system information and the estimated fault cause, and correct the fault point calculated value such that one spot is selected from among the plurality of spots or the probability of existence of fault point is distributed among the plurality of spots, and
the inference unit outputs the location result using the fault point calculated value output from the rule processing unit.

8. The fault point locater according to claim 7, wherein the second inference model is machine-trained using: current information and voltage information at the predetermined spot at a time of simulated fault occurrence at a set supposed fault point that are calculated by a simulator to reflect information on topology and impedance of the power system, as teacher data of the current information and voltage information at the time of fault occurrence; and the supposed fault point as teacher data of the fault point calculated value.

9. The fault point locater according to claim 7, wherein
the storage unit further stores a statistical model configured to, in response to input of a fault cause, output a probabilistic distribution of arc resistance value corresponding to the input fault cause, from the probabilistic distribution at the fault point that is predetermined for each fault cause using an actual value at a time of fault occurrence in the past,
the inference unit inputs the estimated fault cause to the statistical model at the time of fault occurrence and acquires the probabilistic distribution of arc resistance value, and
the inference unit includes an integration processing unit to integrate the corrected fault point calculated value from the rule processing unit and the probabilistic distribution of arc resistance value acquired from the statistical model and output a distribution of the probability of existence of fault point on the power system as the location result.

10. The fault point locater according to claim 6, wherein
the storage unit further stores first system information on topology and impedance of the power system, and
the integration processing unit uses the first system information to convert the probabilistic distribution of arc resistance value into a probabilistic distribution of distance between the one spot or the plurality of spots included in the fault point calculated value and the fault point, and uses the fault point calculated value and the probabilistic distribution of distance to calculate a distribution of the probability of existence of fault point.

11. The fault point locater according to claim 1, wherein the inference unit generates the location result such that correction corresponding to an arc resistance value estimated in accordance with the estimated fault cause is performed on a fault point calculated value calculated using the current information and voltage information acquired at the time of fault occurrence and the estimated fault cause.

12. The fault point locater according to claim 1, wherein the current information and voltage information include a voltage value and a current value at the predetermined spot, and processed data of the voltage value and the current value.

13. The fault point locater according to claim 3, wherein the teacher data of current information and voltage information further includes the current information and voltage information obtained by the data acquisition unit at the time of fault occurrence.

14. The fault point locater according to claim 1, wherein the current information and voltage information include the current information and voltage information at the time of fault occurrence, and the current information and voltage information before fault occurrence and after fault occurrence.

15. A fault point locating system comprising:
the fault point locater according to claim 2; and
a fault point locating server communicatively connected to the fault point locater through a communication network, wherein
the fault point locating server machine-trains the first inference model, using: current information and voltage information at the predetermined spot at a time of simulated fault occurrence at a set supposed fault point that are calculated by a simulator to reflect information on topology and impedance of the power system, as teacher data of the current information and voltage information at the time of fault occurrence; a fault cause corresponding to the surrounding situation at the supposed fault point as teacher data of the fault cause; and the supposed fault point as teacher data of the fault point calculated value, and
the storage unit stores the machine-trained first inference model sent from the fault point locating server.

16. A fault point locating system comprising:
the fault point locater according to claim 7; and
a fault point locating server communicatively connected to the fault point locater through a communication network, wherein
the fault point locating server machine-trains the second inference model, using: current information and voltage information at the predetermined spot at a time of simulated fault occurrence at a set supposed fault point that are calculated by a simulator to reflect information on topology and impedance of the power system, as teacher data of current information and voltage information at the time of fault occurrence; and the supposed fault point as teacher data of the fault point calculated value, and
the storage unit stores the machine-trained second inference model sent from the fault point locating server.

17. A fault point locating system comprising:
the fault point locater according to claim 6; and
a fault point locating server communicatively connected to the fault point locater through a communication network, wherein
the fault point locating server generates a statistical model configured to output a probabilistic distribution of arc resistance value corresponding to an input fault cause, from the probabilistic distribution at the fault point that is predetermined for each fault cause using an actual value at a time of fault occurrence in the past, and
the storage unit stores the statistical model sent from the fault point locating server.

18. The fault point locating system according to claim 15, wherein
the fault point locater is disposed at an electric power station including a substation, and
the location result by the fault point locater is sent to a manned facility via the communication network.

19. A fault point locating method for a power system, comprising:
acquiring current information and voltage information at a predetermined spot at a time of fault occurrence; and
receiving input of the acquired current information and voltage information and an estimated fault cause based on the current information and voltage information, and outputting a location result that quantifies a probability of existence of fault point on the power system.

20. The fault point locating method according to claim 19, further comprising:
storing a machine-trained first inference model receiving input of current information and voltage information at the predetermined spot and a fault cause and outputting a fault point calculated value indicating one spot or a plurality of spots inferred to be likely to be the fault point on the power system, wherein the fault cause reflecting a surrounding situation at each spot in the power system is set in the first inference model; and
outputting the location result based on the fault point calculated value when the current information and voltage information acquired at the time of fault occurrence and an estimated fault cause based on the current information and voltage information are input to the stored first inference model.

21. The fault point locating method according to claim 20, further comprising:
further storing a statistical model configured to output a probabilistic distribution of arc resistance value corresponding to an input fault cause, from the probabilistic distribution at the fault point that is predetermined for each fault cause using an actual value at a time of fault occurrence in the past;
inputting the estimated fault cause to the stored statistical model at the time of fault occurrence; and
integrating the fault point calculated value output from the first inference model and the probabilistic distribution of arc resistance value output from the statistical model, and outputting a distribution of the probability of existence of fault point on the power system as the location result.

22. The fault point locating method according to claim 19, further comprising:
storing a machine-trained second inference model receiving input of current information and voltage information at the predetermined spot and outputting a fault point calculated value corresponding to one or more spots with an equivalent electrical distance from the predetermined spot;
storing second system information indicating a surrounding situation at each spot in the power system;
inputting to the second inference model the current information and voltage information acquired at the time of fault occurrence, and acquiring the fault point calculated value; and
when the fault point calculated value includes a plurality of spots, applying a predetermined rule to a combination of a surrounding situation of each of the plurality of spots indicated by the second system information and the estimated fault cause to correct the fault point calculated value such that one spot is selected from among the plurality of spots or the probability of existence of fault point is distributed among the plurality of spots, and outputting the location result using the corrected fault point calculated value.

23. The fault point locating method according to claim 22, further comprising:
further storing a statistical model configured to, in response to input of a fault cause, output a probabilistic distribution of arc resistance value corresponding to the input fault cause, from the probabilistic distribution at the fault point that is predetermined for each fault cause using an actual value at a time of fault occurrence in the past;
inputting the estimated fault cause to the statistical model at the time of fault occurrence and acquiring the probabilistic distribution of arc resistance value; and
integrating the corrected fault point calculated value and the probabilistic distribution of arc resistance value acquired from the statistical model, and outputting a distribution of the probability of existence of fault point on the power system as the location result.

24. The fault point locating method according to claim 19, wherein the location result is generated and output such that correction corresponding to an arc resistance value estimated in accordance with the estimated fault cause is performed on a fault point calculated value calculated using the current information and voltage information acquired at the time of fault occurrence and the estimated fault cause.

25. The fault point locating method according to claim 20, wherein when the fault point calculated value including the plurality of spots is output, the first inference model outputs the fault point calculated value involving a calculated value of the probability of existence of fault point at each of the plurality of spots.

26. The fault point locating method according to claim 20, wherein the first inference model outputs the fault point calculated value to indicate the one spot where the probability of existence of fault point is largest.
